(19) United States
(12) Patent Application Publication
(10) Pub. No.: US 2023/0153016 A1
(43) Pub. Date: May 18, 2023

(54) SEMICONDUCTOR SYSTEM AND OPERATING METHOD THEREOF

(71) Applicant: SK hynix Inc., Gyeonggi-do (KR)

(72) Inventors: Moon Soo CHOI, Gyeonggi-do (KR); Sung Yeob CHO, Gyeonggi-do (KR)

(21) Appl. No.: 17/679,836

(22) Filed: Feb. 24, 2022

(30) Foreign Application Priority Data
Nov. 16, 2021 (KR) 10-2021-0157723

(51) Int. Cl. G06F 3/06

(52) U.S. Cl. CPC G06F 3/0655; G06F 3/0604; G06F 3/0679

(57) ABSTRACT

A semiconductor system includes a host device, an operating device, and an interface device. The host device performs a data training operation on the basis of state characteristic information on a data driving circuit provided in the operating device and state characteristic information on a data line.

### CROSS-REFERENCES TO RELATED APPLICATION

The present application claims priority under 35 U.S.C. § 119(a) to Korean patent application number 10-2021-0157723, filed on Nov. 16, 2021, which is incorporated herein by reference in its entirety.

### BACKGROUND

### 1. Technical Field

Various embodiments of the present disclosure generally relate to a semiconductor system and an operating method thereof, and more particularly, to a semiconductor system capable of providing a stable data transmission/reception environment between a host device and an operating device, and an operating method thereof.

### 2. Related Art

Recently, as demand for electrical and electronics products increases, interest in semiconductor systems for controlling electrical and electronics products increases. Semiconductor systems are mounted on, for example, a mobile phone, an MP3 player, a laptop computer, a desktop computer, a game machine, a television, an in-vehicle infotainment system, and the like and may serve as a brain for controlling these devices.

In general, a semiconductor system includes a host device that performs a control operation and an operating device that performs a preset operation on the basis of the control operation. The operating device includes, for example, semiconductor memory apparatuses capable of storing data provided from the host device.

In general, a semiconductor memory apparatus is roughly classified into a volatile memory device and a nonvolatile memory device. The volatile memory device has a disadvantage that stored data is lost when power is off, but has an advantage that the degree of integration into a memory cell for storing data is high and an operation speed is high. Examples of the volatile memory device include a static RAM (SRAM), a dynamic RAM (DRAM), a synchronous DRAM (SDRAM), and the like. The nonvolatile memory device has a disadvantage that stored data is retained even though power is off, but has an advantage that the degree of integration is lower and an operation speed is slower than those of the volatile memory device. Examples of the nonvolatile memory device include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM) a ferroelectric RAM (FRAM), and the like.

Furthermore, the host device and the operating device transmit/receive various types of data signals. When an undesired error occurs in data signals transmitted/received between the host device and the operating device, the semiconductor system may not perform a smooth operation. Accordingly, the semiconductor system is being continuously researched and developed in order to provide a stable data transmission/reception environment between the host device and the operating device. However, manufacturers that fabricate the host device and the operating device may be different from each other, and manufacturers that fabricate an interface device, on which the host device and the operating device are mounted, may also be different from each other. The fact that manufacturers that fabricate the host device, the operating device, and the interface device are different from one another implies that there is a possibility of causing a mismatch in transmitting/receiving data signals. The semiconductor system performs a data training operation for overcoming such a problem.

The data training operation is an operation for ensuring an optimal data transmission/reception environment for data signals transmitted/received between the host device and the operating device. More specifically, in the data training operation, a training data signal controlled in a stepwise manner and transmitted/received, in a state in which the host device and the operating device are mounted on the interface device and an optimal transmission/reception environment is detected on the basis of respective scanning results. Furthermore, in the data training operation, driving force, delay amount, power, and the like of a data driving circuit provided in the host device and a data driving circuit provided in the operating device are adjusted according to the optimal transmission/reception environment. Accordingly, the semiconductor system may provide an optimal transmission/reception environment, in which the host device and the operating device transmit/receive data signals, through the data training operation.

As described above, the host device, the operating device, and the interface device may be fabricated by different manufacturers. Accordingly, the data training operation needs to derive all scanning results in order to detect an optimal transmission/reception environment. In order to derive all the scanning results, the training data signal needs to be controlled in a stepwise manner in all possible training ranges, and transmitted and received. As a consequence, much time is required for the data training operation for detecting an optimal transmission/reception environment.

The data training operation is an operation essentially required in order to increase reliability of data transmitted/received between the host device and the operating device. However, the time required for the data training operation may act as a factor that lowers the performance of the semiconductor system.

### SUMMARY

A semiconductor system according to an embodiment of the present disclosure may include: a host device; an operating device including a data driving circuit; and an interface device including a data line that connects the host device and the operating device to each other, wherein the host device is configured to perform a data training operation on the basis of state characteristic information on the data driving circuit of the operating device and state characteristic information on the data line.

An operating method of a semiconductor system according to an embodiment of the present disclosure may include: acquiring state characteristic information on a data line connected between a host device and an operating device; exchanging state characteristic information on a data driving circuit provided in each of the host device and the operating device; performing a data training operation on the basis of the state characteristic information; and performing a normal operation by transmitting/receiving a normal signal between the host device and the operating device through the data line.

### BRIEF DESCRIPTION OF THE DRAWINGS

FIG. 1 is a block diagram illustrating the configuration of a semiconductor system in accordance with an embodiment of the present disclosure.

FIG. 2 is a block diagram illustrating the configuration of a semiconductor system in accordance with an embodiment of the present disclosure.

FIG. 3 is a block diagram illustrating the configuration of a semiconductor system in accordance with an embodiment of the present disclosure.

FIG. 4 is a flowchart illustrating an operating method of a semiconductor system in accordance with an embodiment of the present disclosure.

### DETAILED DESCRIPTION

The present description of the present disclosure provides structural and functional details directed to various embodiments. The scope of the invention, however, is not limited to or by any of the disclosed embodiments nor to any particular detail provided herein. That is, those skilled in the art will understand in view of the present disclosure that any embodiment may be modified in various ways and may have various forms. Accordingly, the invention encompasses all such variations that fall within the scope of the claims including their equivalents. Furthermore, an embodiment does not necessarily include all stated objects or effects nor include only such objects and effects. Accordingly, the scope of the invention is not limited thereby.

Throughout the specification, reference to “an embodiment” or the like is not necessarily to only one embodiment, and different references to any such phrase are not necessarily to the same embodiment(s). The term “embodiments” when used herein does not necessarily refer to all embodiments.

Terms, such as “first” and “second”, are used to distinguish one element from another element that otherwise have the same or similar names. A first element in one instance may be named a second element in another instance without indicating any substantive change in the element itself.

The singular is intended to include the plural, unless clearly expressed otherwise or it is clear from the context that only one is intended. Open-ended terms such as “include” or “have” should be understood as indicating the existence of stated characteristics, numbers, steps, operations, elements, parts, or combination thereof, but not excluding the possibility that one or more other characteristics, numbers, steps, operations, elements, parts, or combination thereof are present or may be added.

In each of steps, symbols (e.g., a, b, and c) are used for convenience of a description, not necessarily to indicate any particular order of steps or operations. Consistent with the teachings herein, steps/operations may be performed in any suitable order, unless a specific order is clearly described or such order is indicated by the context. In some cases, two or more steps/operations may be performed substantially at the same time.

All the terms used herein, including technological or scientific terms, have the same meanings as typically understood by those skilled in the art, unless otherwise defined. Terms defined in commonly used dictionaries should be construed in the context of the related technology and should not be construed as ideal or in an excessively formal way, unless clearly defined in the application.

Various embodiments of the present disclosure are directed to providing a semiconductor system capable of performing a data training operation on the basis of state characteristic information on a data line connecting a host device and an operating device, and state characteristic information on a data driving circuit, and an operating method thereof.

An embodiment of the present disclosure has an effect capable of providing an optimized transmission/reception environment through a more accurate and faster data training operation.

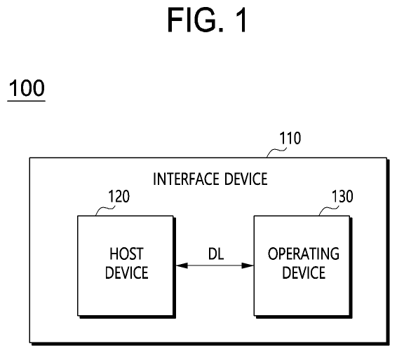

FIG. 1 is a block diagram illustrating the configuration of a semiconductor system 100 in accordance with an embodiment of the present disclosure.

Referring to FIG. 1, the semiconductor system 100 may be configured to perform a desired operation through a circuit operation. The semiconductor system 100 may be fabricated as any of various types of packages such as a package on package (POP), a system in package (SIP), a system on chip (SOC), a multichip package (MCP), a chip on board (COB), a wafer-level fabricated package (WFP), and a wafer-level stack package (WSP). The semiconductor system 100 may include an interface device 110, a host device 120 and an operating device 130.

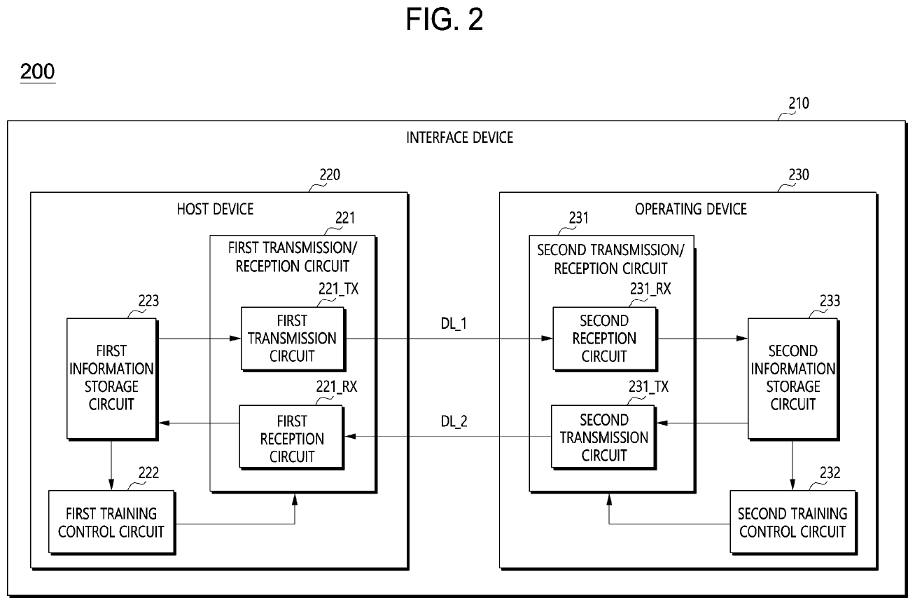

The interface device 110 may be configured to connect the host device 120 and the operating device 130 to each other. The host device 120 and the operating device 130 may be mounted on the interface device 110. The interface device 110 may include a data line DL that connects the host device 120 and the operating device 130 to each other. As will be described in more detail with reference to FIG. 2, the data line DL may include a first data line DL_1 (see FIG. 2) which may transfer a signal from the host device 120 and a second data line DL_2 (see FIG. 2) which may transfer a signal to the host device 120. The first data line DL_1 may transfer a signal to the operating device 130, and the second data line DL_2 may transfer a signal from the operating device 130. For convenience of description, FIG. 1 illustrates only one data line DL, but the data line DL may be designed as a plurality of data lines.

The host device 120 may be configured to control the operating device 130. The operating device 130 may be configured to perform a preset operation under the control of the host device 120.

In order to control the operating device 130, the host device 120 may provide, for example, a command signal, a data signal, various control signals, and the like to the operating device 130 through the data line DL. For example, when the operating device 130 serves as a memory, the host device 120 may additionally provide an address signal corresponding to the location of a memory bank where a data signal is to be stored. Then, the operating device 130 may output an output signal through the data line DL under the control of the host device 120, and the host device 120 may receive the signal transferred through the data line DL.

The host device 120 and the operating device 130 may perform various data transmission/reception operations according to a transmission/reception protocol set by the host device 120. For example, the host device 120 and the operating device 130 may perform transmission/reception operations by using a double data rate (DDR), a DDR2, a DDR3, a DDR4, a low power DDR (LPDDR), a universal serial bus (USB), a universal flash storage (UFS), a multi-media card (MMC), an embedded MMC, an advanced technology attachment (ATA), a parallel advanced technology attachment (PATA), a serial advanced technology attachment (SATA), a small computer system interface (SCSI), an enhanced small disk interface (ESDI), integrated drive electronics (IDE), a serial attached SCSI (SAS), a peripheral component interconnection (PCI), a PCI express (PCIe), a firewire, a non-volatile memory express (NVMe), and the like.

As will be described in more detail below, each of the host device 120 and the operating device 130 may include a data driving circuit (not illustrated) connected to the end of the data line DL. The host device 120 may perform a data training operation on the basis of state characteristic information on the data driving circuit provided in the operating device 130 and state characteristic information on the data line DL.

For reference, the data driving circuit may include a second transmission/reception circuit 231 of an operating device 230 to be described with reference to FIG. 2, and as will be described below, the second transmission/reception circuit 231 may include a second reception circuit 231_RX and a second transmission circuit 231_TX. The state characteristic information of the data driving circuit may include state characteristic information on at least one of the second reception circuit 231_RX and the second transmission circuit 231_TX.

The state characteristic information on the data line DL and the state characteristic information on the data driving circuit may each include a characteristic value corresponding to at least one of, for example, material information, process information, design information, and operation state information on each configuration. For example, when the data line DL is designed to have a certain shape and length through a certain process by using a certain material and has a certain operation state according to temperature, voltage, transmission speed, and the like, state characteristic information on the data line DL may include characteristic value information corresponding to each of material information, process information, design information, and operation state information on the data line DL.

The semiconductor system 100 in accordance with an embodiment of the present disclosure may perform a data training operation on the basis of state characteristic information on the data driving circuit provided in the operating device 130 and state characteristic information on the data line DL. As compared to the related art, the semiconductor system 100 may reduce a time required for the data training operation by performing the data training operation in a training range corresponding to various state characteristic information.

The fact that the data training operation time may be reduced means that it is possible to secure more time for performing an additional operation, for example, a fine training operation and the like may be performed within a data training operation time defined by specifications of the host device 120 and the operating device 130. Accordingly, the semiconductor system 100 may provide an optimized transmission/reception environment for the host device 120 and the operating device 130 by performing a more accurate and faster data training operation.

FIG. 2 is a block diagram illustrating the configuration of a semiconductor system 200 in accordance with an embodiment of the present disclosure.

Referring to FIG. 2, the semiconductor system 200 may include an interface device 210, a host device 220, and the operating device 230. The interface device 210, the host device 220, and the operating device 230 may correspond to the interface device 110, the host device 120 and the operating device 130 in FIG. 1, respectively.

The host device 220 may include a first transmission/reception circuit 221 and a first training control circuit 222.

The first transmission/reception circuit 221 may be connected to the first and second data lines DL_1 and DL_2 and configured to transmit/receive signals. The first transmission/reception circuit 221 may include a first transmission circuit 221_TX and a first reception circuit 221_RX.

The first transmission circuit 221_TX may be configured to output state characteristic information on a data driving circuit of the host device 220. The first transmission circuit 221_TX may output state characteristic information on the first transmission/reception circuit 221 of the host device 220. The state characteristic information on the first transmission/reception circuit 221 may include state characteristic information on at least one of the first transmission circuit 221_TX and the first reception circuit 221_RX.

Accordingly, the first transmission circuit 221_TX may output the state characteristic information on at least one of the first transmission circuit 221_TX and the first reception circuit 221_RX, which is stored in a first information storage circuit 223 to be described below, to the second reception circuit 231_RX before a data training operation. Then, the first transmission circuit 221_TX may output a training data signal to the second reception circuit 231_RX during the data training operation. Then, the first transmission circuit 221_TX may output a normal signal to the second reception circuit 231_RX after the data training operation is completed. The normal signal may include the command signal, the data signal, various control signals, the address signal, and the like described above. Although not illustrated in the drawing, the first transmission circuit 221_TX may include a buffer circuit, a de-emphasis circuit, a pre-shoot circuit, and the like. Accordingly, as the de-emphasis circuit and the pre-shoot circuit are controlled, the first transmission circuit 221_TX may perform a data training operation for the data transmission operation of the first transmission circuit 221_TX.

Next, the first reception circuit 221_RX may be configured to receive state characteristic information on a data driving circuit of the operating device 230. The first reception circuit 221_RX may receive state characteristic information on the second transmission/reception circuit 231 of the operating device 230. The state characteristic information on the second transmission/reception circuit 231 may include state characteristic information on at least one of the second reception circuit 231_RX and the second transmission circuit 231_TX.

Accordingly, the first reception circuit 221_RX may receive the state characteristic information on at least one of the second reception circuit 231_RX and the second transmission circuit 231_TX, which is stored in a second information storage circuit 233 to be described below, through the second transmission circuit 231_TX before the data training operation and may transfer the received state characteristic information to the first information storage circuit 223. Then, the first reception circuit 221_RX may receive the training data signal from the second transmission circuit 231_TX during the data training operation. Then, the reception circuit 221_RX may receive the normal signal from the second transmission circuit 231_TX after the data training operation is completed. The normal signal may include the command signal, the data signal, various control signals, the address signal, and the like described above. Although not illustrated in the drawing, the first reception circuit 221_RX may include a buffer circuit, an equalizing circuit, and the like. Accordingly, as the equalizing circuit is controlled, the first reception circuit 221_RX may perform a data training operation for the data reception operation of the first reception circuit 221_RX.

Moreover, the first training control circuit 222 may be configured to control the data training operation on the first transmission/reception circuit 221 on the basis of the state characteristic information on the data driving circuit of the operating device 230 and the state characteristic information on the data line. The first training control circuit 222 may control the data training operation on the first transmission/reception circuit 221 on the basis of the state characteristic information on at least one of the second reception circuit 231_RX and the second transmission circuit 231_TX of the operating device 230 and the state characteristic information on at least one of the first and second data lines DL_1 and DL_2.

Furthermore, the first training control circuit 222 may control the data training operation on the first transmission/reception circuit 221 on the basis of the state characteristic information on the data driving circuit of the host device 220 and the state characteristic information on the data line. The first training control circuit 222 may control the data training operation on the first transmission/reception circuit 221 on the basis of the state characteristic information on at least one of the first transmission circuit 221_TX and the first reception circuit 221_RX and the state characteristic information on at least one of the first and second data lines DL_1 and DL_2.

More specifically, for the data training operation on the first transmission circuit 221_TX, the first training control circuit 222 may use the state characteristic information on at least one of the first transmission circuit 221_TX and the second reception circuit 231_RX together with the state characteristic information on the first data line DL_1. For example, a parameter value and the like of the first transmission circuit 221_TX may be adjusted through the data training operation on the first transmission circuit 221_TX. Furthermore, for the data training operation on the first reception circuit 221_RX, the first training control circuit 222 may use the state characteristic information on at least one of the first reception circuit 221_RX and the second transmission circuit 231_TX together with the state characteristic information on the second data line DL_2. For example, a terminal resistance value and the like of the first reception circuit 221_RX may be adjusted through the data training operation on the first reception circuit 221_RX.

In brief, the first training control circuit 222 may perform the data training operation on the first transmission/reception circuit 221 by using state characteristic information on the first and second transmission/reception circuits 221 and 231, state characteristic information on the first and second data lines DL_1 and DL_2, and the like. Accordingly, the first transmission/reception circuit 221 may perform the data training operation only within a data training range corresponding to the state characteristic information, other than the entire data training range. As a consequence, this makes it possible to minimize the data training operation time for the first transmission/reception circuit 221.

The semiconductor system 200 in accordance with an embodiment of the present disclosure may control the data training operation on the first transmission/reception circuit 221 on the basis of a data training range corresponding to state characteristic information. Accordingly, in the semiconductor system 200, the host device 220 may perform a faster data training operation.

Additionally, the host device 220 may include the first information storage circuit 223. The first information storage circuit 223 may be configured to store the state characteristic information on the second transmission/reception circuit 231, which is the data driving circuit of the operating device 230, and the state characteristic information on the first and second data lines DL_1 and DL_2. The first information storage circuit 223 may also store the state characteristic information on the first transmission/reception circuit 221 of the host device 220.

The state characteristic information on the first transmission/reception circuit 221 may be provided from a manufacturer that fabricates the host device 220, and the state characteristic information on the first and second data lines DL_1 and DL_2 may be provided from a manufacturer that fabricates the interface device 210. The state characteristic information on the second transmission/reception circuit 231 may be provided from a manufacturer that fabricates the operating device 230. Particularly, the state characteristic information on the second transmission/reception circuit 231 may be stored in the second information storage circuit 233 to be described below, and may be provided through the second data line DL_2. The first information storage circuit 223 may provide the stored state characteristic information to the first training control circuit 222.

The semiconductor system 200 in accordance with an embodiment of the present disclosure may store the state characteristic information on the first and second transmission/reception circuits 221 and 231 and the state characteristic information on the first and second data lines DL_1 and DL_2 in the first information storage circuit 223.

The operating device 230 in FIG. 2 may include the second transmission/reception circuit 231 and a second training control circuit 232.

The second transmission/reception circuit 231 may be connected to the first and second data lines DL_1 and DL_2 and configured to transmit/receive signals. The second transmission/reception circuit 231 may include the second reception circuit 231_RX and the second transmission circuit 231_TX.

The second reception circuit 231_RX may be configured to receive the state characteristic information on the data driving circuit of the host device 220. The second reception circuit 231_RX may receive the state characteristic information on the first transmission/reception circuit 221 of the host device 220.

Accordingly, the second reception circuit 231_RX may receive the state characteristic information on at least one of the first transmission circuit 221_TX and the first reception circuit 221_RX, which is stored in the first information storage circuit 223, through the first transmission circuit 221_TX before the data training operation and may transfer the received state characteristic information to the second information storage circuit 233. Then, the second reception circuit 231_RX may receive the training data signal from the first transmission circuit 221_TX during the data training operation. Then, the second reception circuit 231_RX may receive the normal signal from the first transmission circuit 221_TX after the data training operation is completed. The second reception circuit 231_RX may include a buffer circuit, an equalizing circuit, and the like, similar to the first reception circuit 221_RX. Accordingly, as the equalizing circuit is controlled, the second reception circuit 231_RX may perform a data training operation for the data reception operation of the second reception circuit 231_RX.

Next, the second transmission circuit 231_TX may be configured to output the state characteristic information on the data driving circuit of the operating device 230. The second transmission circuit 231_TX may output the state characteristic information on the second transmission/reception circuit 231 of the operating device 230.

Accordingly, the second transmission circuit 231_TX may output the state characteristic information on at least one of the second reception circuit 231_RX and the second transmission circuit 231_TX, which is stored in the second information storage circuit 233, to the first reception circuit 221_RX before the data training operation. Then, the second transmission circuit 231_TX may output the training data signal to the first reception circuit 221_RX during the data training operation. Then, the second transmission circuit 231_TX may output the normal signal to the first reception circuit 221_RX after the data training operation is completed. The second transmission circuit 231_TX may include a buffer circuit, a de-emphasis circuit, a pre-shoot circuit, and the like, similar to the first transmission circuit 221_TX. Accordingly, as the de-emphasis circuit and the pre-shoot circuit are controlled, the second transmission circuit 231_TX may perform a data training operation for the data transmission operation of the second transmission circuit 231_TX.

Moreover, the second training control circuit 232 may be configured to control the data training operation on the second transmission/reception circuit 231 on the basis of the state characteristic information on the data driving circuit of the host device 220 and the state characteristic information on the data line. The second training control circuit 232 may control the data training operation on the second transmission/reception circuit 231 on the basis of the state characteristic information on at least one of the first transmission circuit 221_TX and the first reception circuit 221_RX of the host device 220, and the state characteristic information on at least one of the first and second data lines DL_1 and DL_2.

Furthermore, the second training control circuit 232 may control the data training operation on the second transmission/reception circuit 231 on the basis of the state characteristic information on the data driving circuit of the operating device 230 and the state characteristic information on the data line. The second training control circuit 232 may control the data training operation on the second transmission/reception circuit 231 on the basis of the state characteristic information on at least one of the second reception circuit 231_RX and the second transmission circuit 231_TX, and the state characteristic information on at least one of the first and second data lines DL_1 and DL_2.

More specifically, for the data training operation on the second reception circuit 231_RX, the second training control circuit 232 may use the state characteristic information on at least one of the first transmission circuit 221_TX and the second reception circuit 231_RX together with the state characteristic information on the first data line DL_1. For example, a terminal resistance value and the like of the second reception circuit 231_RX may be adjusted through the data training operation on the second reception circuit 231_RX. Furthermore, for the data training operation on the second transmission circuit 231_TX, the second training control circuit 232 may use the state characteristic information on at least one of the first reception circuit 221_RX and the second transmission circuit 231_TX together with the state characteristic information of the second data line DL_2. For example, a parameter value and the like of the second transmission circuit 231_TX may be adjusted through the data training operation on the second transmission circuit 231_TX.

In brief, the second training control circuit 232 may perform the data training operation on the second transmission/reception circuit 231 by using the state characteristic information on the first and second transmission/reception circuits 221 and 231, the state characteristic information on the first and second data lines DL_1 and DL_2, and the like. Accordingly, the second transmission/reception circuit 231 may perform the data training operation only within a data training range corresponding to the state characteristic information, other than the entire data training range. As a consequence, this makes it possible to minimize the data training operation time for the second transmission/reception circuit 231.

The semiconductor system 200 in accordance with an embodiment of the present disclosure may control the data training operation on the second transmission/reception circuit 231 on the basis of a data training range corresponding to state characteristic information. Accordingly, the semiconductor system 200 may perform a faster data training operation from the perspective of the operating device 230.

Additionally, the operating device 230 may include the second information storage circuit 233. The second information storage circuit 233 may be configured to store the state characteristic information on the first transmission/reception circuit 221, which is a data driving circuit of the host device 220, and the state characteristic information on the first and second data lines DL_1 and DL_2. The second information storage circuit 233 may also the store state characteristic information on the second transmission/reception circuit 231 of the operating device 230.

The state characteristic information on the second transmission/reception circuit 231 may be provided from a manufacturer that fabricates the operating device 230, and the state characteristic information on the first transmission/reception circuit 221 may be provided from a manufacturer that fabricates the host device 220. Particularly, the state characteristic information on the first transmission/reception circuit 221 may be stored in the first information storage circuit 223, and may be provided through the first data line DL_1. The second information storage circuit 233 may provide the stored state characteristic information to the second training control circuit 232.

The semiconductor system 200 in accordance with an embodiment of the present disclosure may store the state characteristic information on the first and second transmission/reception circuits 221 and 231 and the state characteristic information on the first and second data lines DL_1 and DL_2 in the second information storage circuit 233.

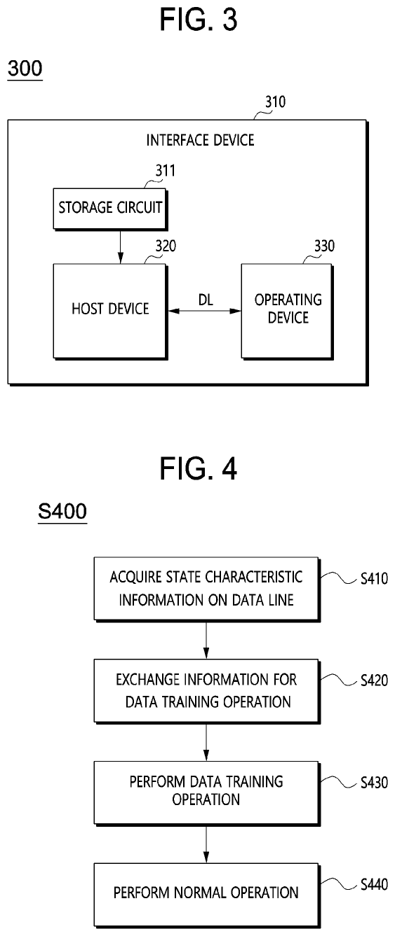

FIG. 3 is a block diagram illustrating the configuration of a semiconductor system 300 in accordance with an embodiment of the present disclosure.

Referring to FIG. 3, the semiconductor system 300 may include an interface device 310, a host device 320, and an operating device 330. The interface device 310, the host device 320, and the operating device 330 may correspond to the interface device 110, the host device 120 and the operating device 130 in FIG. 1, respectively. The interface device 310 of the semiconductor system 300 in FIG. 3 is different from the interface device 110 of the semiconductor system 100 in FIG. 1. Therefore, description will be given based on the difference.

The interface device 310 may provide the state characteristic information on the data line DL to at least one of the host device 320 and the operating device 330. For convenience of description, FIG. 3 illustrates an example in which the interface device 310 provides the state characteristic information on the data line DL to the host device 320.

That is, the interface device 310 may provide the state characteristic information on the data line DL to the host device 320, and may include a storage circuit 311 for this purpose. As described above, a manufacturer that fabricates the interface device 310 may provide the state characteristic information on the data line DL, and the storage circuit 311 may store the characteristic information. The state characteristic information on the data line DL, stored in the storage circuit 311, may be transferred to, for example, the first information storage circuit 223 in FIG. 2. Accordingly, the host device 320 may utilize the state characteristic information on the data line DL during the data training operation.

Subsequently, in FIG. 3, the state characteristic information on the data line DL may be stored in the first information storage circuit 223 in FIG. 2. Furthermore, the state characteristic information on the data line DL, stored in the first information storage circuit 223, may be transferred to the operating device 330 through the data line DL. Accordingly, the operating device 330 may also utilize the state characteristic information on the data line DL during the data training operation.

The semiconductor system 300 in accordance with an embodiment of the present disclosure may include the storage circuit 311 for storing the state characteristic information on the data line DL. Accordingly, the host device 320 and the operating device 330 may receive the state characteristic information on the data line DL for the data training operation through the storage circuit 311.

FIG. 4 is a flowchart illustrating an operating method S400 of a semiconductor system in accordance with an embodiment of the present disclosure.

Referring to FIG. 4, the operating method S400 of the semiconductor system may include an operation S410 of acquiring state characteristic information on a data line, an operation S420 of exchanging information for a data training operation, an operation S430 of performing the data training operation, and an operation S440 of performing a normal operation.

The operation S410 of acquiring the state characteristic information on the data line may be an operation of acquiring the state characteristic information on the first and second data lines DL_1 and DL_2 in FIG. 2. The semiconductor system 200 may acquire the state characteristic information on the first and second data lines DL_1 and DL_2 by storing the state characteristic information in the first and second information storage circuits 223 and 233.

In this regard, in the operation S410 of acquiring the state characteristic information on the data line in FIG. 3, the state characteristic information on the data line DL may be acquired through the storage circuit 311. Furthermore, the state characteristic information on the data line DL acquired through the storage circuit 311 may be stored in, for example, the host device 320 as described above. Then, the state characteristic information on the data line DL stored in the host device 320 may be transferred to the operating device 330 through the data line DL.

The operation S420 of exchanging the information for the data training operation may be an operation of exchanging the state characteristic information on the data driving circuit provided in each of the host device 220 and the operating device 230 in FIG. 2. As described above, the host device 220 in FIG. 2 may include the first transmission/reception circuit 221 that is a data driving circuit. The operating device 230 may include the second transmission/reception circuit 231 that is a data driving circuit. The first information storage circuit 223 may store the state characteristic information on the first transmission/reception circuit 221, and the second information storage circuit 233 may store the state characteristic information on the second transmission/reception circuit 231.

Accordingly, the host device 220 may transfer the state characteristic information on the first transmission/reception circuit 221 to the operating device 230 through the first data line DL_1. The operating device 230 may transfer the state characteristic information on the second transmission/reception circuit 231 to the host device 220 through the second data line DL_2. The host device 220 and the operating device 230 may exchange the state characteristic information on the data driving circuit provided in each of them.

The operation S430 of performing the data training operation may be an operation of performing the data training operation on the basis of the state characteristic information. The operation S430 of performing the data training operation may be performed by the first training control circuit 222 and the second training control circuit 232 in FIG. 2.

As described above, the first training control circuit 222 may perform the data training operation on the first transmission/reception circuit 221 on the basis of the state characteristic information stored in the first information storage circuit 223. In this case, the first information storage circuit 223 may store the state characteristic information on the first and second transmission/reception circuits 221 and 231, the state characteristic information on the first and second data lines DL_1 and DL_2, and the like. The second training control circuit 232 may perform the data training operation on the second transmission/reception circuit 231 on the basis of the state characteristic information stored in the second information storage circuit 233. In this case, the second information storage circuit 233 may store the state characteristic information on the first and second transmission/reception circuits 221 and 231, the state characteristic information on the first and second data lines DL_1 and DL_2, and the like.

Accordingly, in the operation S430 of performing the data training operation, the data training operation on the host device 220 and the operating device 230 may be controlled in a data training range corresponding to the acquired state characteristic information on the first and second data lines DL_1 and DL_2 and the exchanged state characteristic information on the first and second transmission/reception circuits 221 and 231. In this case, the first and second data lines DL_1 and DL_2 may transmit/receive a training data signal.

The operation S440 of performing the normal operation may be an operation of performing the normal operation by transmitting/receiving a normal signal between the host device 220 and the operating device 230 through the first and second data lines DL_1 and DL_2 in FIG. 2. During the normal operation, the host device 220 and the operating device 230 may transmit/receive the normal signal through the first and second data lines DL_1 and DL_2.

The operating method S400 of the semiconductor system in accordance with an embodiment of the present disclosure may minimize a data training range by acquiring state characteristic information on a data line and exchanging information for a data training operation. Accordingly, the semiconductor system may minimize a time required for the data training operation for providing an optimal transmission/reception environment.

Although various embodiments have been described for illustrative purposes, it will be apparent to those skilled in the art that various changes and modifications may be made without departing from the spirit and scope of the invention as defined in the following claims.

What is claimed is:

1. A semiconductor system comprising:
a host device;
an operating device including a data driving circuit; and
an interface device including a data line that connects the host device and the operating device to each other,
wherein the host device is configured to perform a data training operation on the basis of state characteristic information on the data driving circuit of the operating device and state characteristic information on the data line.

2. The semiconductor system according to claim 1,
wherein the data driving circuit includes a reception circuit and a transmission circuit, and
wherein the state characteristic information on the data driving circuit includes state characteristic information on at least one of the reception circuit and the transmission circuit.

3. The semiconductor system according to claim 1, wherein the state characteristic information on the data driving circuit of the operating device or the data line includes characteristic value information corresponding to at least one of material information, process information, design information, and operation state information on the data driving circuit of the operating device or the data line.

4. The semiconductor system according to claim 1, wherein the host device comprises:
a first transmission/reception circuit connected to the data line and configured to transmit/receive a signal; and
a first training control circuit configured to control the data training operation on the first transmission/reception circuit on the basis of the state characteristic information on the data driving circuit of the operating device and the state characteristic information on the data line.

5. The semiconductor system according to claim 4, wherein the first transmission/reception circuit comprises:
a first transmission circuit configured to output state characteristic information on a data driving circuit of the host device; and
a first reception circuit configured to receive the state characteristic information on the data driving circuit of the operating device.

6. The semiconductor system according to claim 5,
wherein the first transmission circuit outputs the state characteristic information on the data driving circuit of the host device before the data training operation, and
wherein the first transmission circuit is further configured to output a normal signal after the data training operation is completed.

7. The semiconductor system according to claim 5,
wherein the first reception circuit receives the state characteristic information on the data driving circuit of the operating device before the data training operation, and
wherein the first reception circuit is further configured to receive a normal signal after the data training operation is completed.

8. The semiconductor system according to claim 4, wherein the first training control circuit controls the data training operation on the first transmission/reception circuit on the basis of state characteristic information on a data driving circuit of the host device and the state characteristic information on the data line.

9. The semiconductor system according to claim 1, wherein the host device comprises a first information storage circuit configured to store the state characteristic information on the data driving circuit of the operating device and the state characteristic information on the data line.

10. The semiconductor system according to claim 1, wherein the operating device further comprises:
a second transmission/reception circuit connected to the data line and configured to transmit/receive a signal; and
a second training control circuit configured to control the data training operation on the second transmission/reception circuit on the basis of state characteristic information on a data driving circuit of the host device and the state characteristic information on the data line.

11. The semiconductor system according to claim 10, wherein the second transmission/reception circuit comprises:
a second reception circuit configured to receive the state characteristic information on the data driving circuit of the host device; and
a second transmission circuit configured to output the state characteristic information on the data driving circuit of the operating device.

12. The semiconductor system according to claim 11,
wherein the second reception circuit receives the state characteristic information on the data driving circuit of the host device before the data training operation, and
wherein the second reception circuit is further configured to receive a normal signal after the data training operation is completed.

13. The semiconductor system according to claim 11,
wherein the second transmission circuit outputs the state characteristic information on the data driving circuit of the operating device before the data training operation, and
wherein the second transmission circuit is further configured to output a normal signal after the data training operation is completed.

14. The semiconductor system according to claim 10, wherein the second training control circuit controls the data training operation on the second transmission/reception circuit on the basis of the state characteristic information on the data driving circuit of the operating device and the state characteristic information on the data line.

15. The semiconductor system according to claim 1, wherein the operating device further comprises a second information storage circuit configured to store state characteristic information on a data driving circuit of the host device and the state characteristic information on the data line.

16. The semiconductor system according to claim 1, wherein the interface device is configured to provide the state characteristic information on the data line to at least one of the host device and the operating device.

17. An operating method of a semiconductor system, the operating method comprising:
acquiring state characteristic information on a data line connected between a host device and an operating device;
exchanging state characteristic information on a data driving circuit provided in each of the host device and the operating device;
performing a data training operation on the basis of the state characteristic information; and
performing a normal operation by transmitting/receiving a normal signal between the host device and the operating device through the data line.

18. The operating method according to claim 17, wherein the acquiring the state characteristic information on the data line includes transferring, through the data line, the state characteristic information on the data line from one of the host device and the operating device to the other one of the host device and the operating device.

19. The operating method according to claim 17, wherein the exchanging the state characteristic information comprises:
transferring the state characteristic information on the data driving circuit of the host device to the operating device through the data line; and
transferring the state characteristic information on the data driving circuit of the operating device to the host device through the data line.

20. The operating method according to claim 17, wherein the performing the data training operation includes controlling the data training operation on the host device and the operating device in a data training range corresponding to the state characteristic information on the data line and the exchanged state characteristic information.

21. An operating method of a device, the operating method comprising:
obtaining information on each of a first circuit, a second circuit and a transmission line;
training the first circuit based on the information; and
controlling the first circuit to exchange data with the second circuit through the transmission line.
